(19) United States
(12) Patent Application Publication
(10) Pub. No.: US 2011/0057332 A1
(43) Pub. Date: Mar. 10, 2011

(54) SEMICONDUCTOR CHIP WITH CONDUCTIVE ADHESIVE LAYER AND METHOD OF MANUFACTURING THE SAME, AND METHOD OF MANUFACTURING SEMICONDUCTOR DEVICE

(75) Inventor: Tsutomu IWAMI, Kanagawa (JP)

(73) Assignee: RENESAS ELECTRONICS CORPORATION, Kanagawa (JP)

(21) Appl. No.: 12/876,349

(22) Filed: Sep. 7, 2010

(30) Foreign Application Priority Data
Sep. 7, 2009 (JP) 2009-205583

(51) Int. Cl. H01L 23/12; H01L 21/78

(52) U.S. Cl. 257/783; 438/462; 257/E21.599; 257/E23.003

(57) ABSTRACT

A method of manufacturing a semiconductor chip with a conductive adhesive layer including steps of: forming a conductive adhesive layer on back side of a wafer on which a semiconductor element is formed; laminating a flexible substrate on back side of the conductive adhesive layer; forming a dicing groove which reaches from a front of the wafer to the conductive adhesive layer and a bottom of which is in the conductive adhesive layer; pressing from back side of the flexible substrate in such a way that the conductive adhesive layer is cut with the dicing groove as an origin point; and separating the flexible substrate from the conductive adhesive layer.

### INCORPORATION BY REFERENCE

This application is based upon and claims the benefit of priority from Japanese patent application No. 2009-205583, filed on Sep. 7, 2009, the disclosure of which is incorporated herein in its entirety by reference.

### BACKGROUND

1. Field of the Invention

The present invention relates to a semiconductor chip with a conductive adhesive layer and a method of manufacturing the same and, in addition, to a method of manufacturing a semiconductor device that implement the semiconductor chip.

2. Description of Related Art

Conventionally, various kinds of suggestions about a method of dicing a wafer have been proposed. FIGS. 8A to 8F are sectional views to explain a method of forming a solder layer in a semiconductor chip disclosed in Japanese Unexamined Patent Application Publication No. 06-021109. At first, as shown in FIG. 8A, a first adhesive layer 131 is formed on a substrate 130. Subsequently, as shown in FIG. 8B, a solder layer 120 is formed. Then, as shown in FIG. 8C, a second adhesive layer 132 is formed on the solder layer 120. Next, as shown in FIG. 8D, a wafer 150 is adhered on the second adhesive layer 132. Then, as shown in FIG. 8E, dicing grooves 160, which reach from the surface of the wafer 150 to the substrate 130, are formed by using a dicing blade (dicer). Continuously, the adhesive strength between the first adhesive layer 131 and the solder layer 120 is reduced by irradiating ultraviolet rays from the front of the substrate 130. Thereby, as shown in FIG. 8F, semiconductor chips 110 with solder layer are taken out.

FIG. 9, which is disclosed in Japanese Unexamined Patent Application Publication 08-236484, is a sectional view to explain a method of dicing a wafer. In FIG. 9, the reference numeral 250 denotes a wafer, the reference numeral 230 denotes a protective tape, the reference numeral 232 denotes a wafer table, the reference numeral 233 denotes a resilient base, and the reference numeral 234 denotes a braking roller. The wafer sheet 230 is attached onto the back side of the wafer 250 on which a semiconductor element is formed. The major surface of the wafer 250 is coated by the protective tape 231.

From the front of the wafer 250, dicing grooves (braking spare lines) 260 are formed by a dicing blade. After following the dicing grooves 260, the major surface of the wafer 250 is reversed. Then the protective tape 231 is stuck to the wafer 250, and it is set on the resilient base 233. Subsequently, the wafer 250 is pushed by using the braking roller 234, which has the braking mechanism in which a load feedback control is available. Thereby the resilient base 233 is pushed and is elastically-deformed, and the wafer 250 is sunk, as shown in FIG. 9. As a result, braking lines 270 are formed, the wafer 250 is divided, and the semiconductor chip is taken out.

### SUMMARY

As described in Japanese Unexamined Patent Application Publication No. 06-021109, because the solder layer is formed beforehand on the back side of the semiconductor chip, the packaging process in which the semiconductor chip is implemented on a lead frame, a packaging substrate or the like, can be facilitated. However, according to the method disclosed in Japanese Unexamined Patent Application Publication No. 06-021109, in a die bonding process, a semiconductor chip divided into a unit piece cannot be picked up in some cases. This is because solder burrs (not shown) are formed due to a ductility of the solder layer 120, the first adhesive layer 131 and the substrate 130 when dicing grooves 160 are formed in the wafer 150, and the solder burrs bite into the first adhesive layer 131 and the substrate 130. The adhesion strength between the solder layer 120 and the substrate 130 increases due to the biting of the solder burrs. This causes a problem that it might be impossible to pick up the semiconductor chip.

In Japanese Unexamined Patent Application Publication No. 08-236484, a method to form a solder layer beforehand on back side of a semiconductor chip is not disclosed.

In a first exemplary aspect of the present invention, a method of manufacturing a semiconductor chip with a conductive adhesive layer forming a conductive adhesive layer on back side of a wafer on which a semiconductor element is formed; laminating a flexible substrate on back side of the conductive adhesive layer; forming a dicing groove which reaches from a front of the wafer to the conductive adhesive layer and a bottom of which is in the conductive adhesive layer; pressing from back side of the flexible substrate in such a way that the conductive adhesive layer is cut with the dicing groove as an origin point; and separating the flexible substrate from the conductive adhesive layer.

In a second exemplary aspect of the present invention, a method of manufacturing a semiconductor device that implements a semiconductor chip with a conductive adhesive layer includes manufacturing a semiconductor chip; mounting the semiconductor chip so that the conductive adhesive layer, which is formed on back side of the semiconductor chip, is attached on a substrate; and implementing the semiconductor chip with conductive adhesive layer on the substrate by a reflow process. The method of manufacturing the semiconductor chip with conductive adhesive layer includes forming the conductive adhesive layer on back side of the wafer on which a semiconductor element is formed; laminating a flexible substrate on back side of the conductive adhesive layer; forming a dicing groove which reaches from a front of the wafer to the conductive adhesive layer and a bottom of which is in the conductive adhesive layer; pressing from back side of the flexible substrate in such a way that the conductive adhesive layer is cut with the dicing groove as an origin point; and separating the flexible substrate from the conductive adhesive layer.

In a third exemplary aspect of the invention, a semiconductor chip with a conductive adhesive layer includes a semiconductor chip; and a conductive adhesive layer formed on back side of the semiconductor chip. Solder burrs which are substantively extended in the major plane direction of the semiconductor chip is formed in a near field region of the back side that is opposite to a side where the semiconductor chip is formed, at a sidewall of the conductive adhesive layer, when the conductive adhesive layer is cut.

The present invention has an exemplary advantage providing a semiconductor chip, method of a manufacturing the same, and method of a manufacturing semiconductor device that can achieve high production yield.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1A is a schematic sectional view of a semiconductor chip with a conductive adhesive layer according to a first exemplary embodiment of the present invention;

FIG. 1B is a schematic sectional view of a semiconductor device according to the first exemplary embodiment;

FIG. 2 is a schematic top surface to explain a wafer;

FIGS. 3A to 3G are sectional views showing a method of manufacturing the semiconductor chip with the conductive adhesive layer of the first exemplary embodiment;

FIG. 4 is a schematic sectional view of the semiconductor chip with a conductive adhesive layer according to a second exemplary embodiment of the present invention;

FIGS. 5A to 5D are sectional views showing a method of manufacturing the semiconductor chip with the conductive adhesive layer of the second exemplary embodiment;

FIG. 6 is a schematic sectional view of the semiconductor chip with conductive adhesive layer according to a third exemplary embodiment of the present invention;

FIGS. 7A to 7D are sectional views showing a method of manufacturing the semiconductor chip with the conductive adhesive layer of the third exemplary embodiment;

FIGS. 8A to 8F are sectional views showing a method of manufacturing a semiconductor chip with a solder layer disclosed in Japanese Unexamined Patent Application Publication No. 06-021109; and

FIG. 9 is a sectional views showing a method of manufacturing a semiconductor chip disclosed in Japanese Unexamined Patent Application Publication No. 08-236484.

### DETAILED DESCRIPTION OF THE EXEMPLARY EMBODIMENTS

Exemplary embodiments of the present invention will be described below. Note that other embodiments may also fall within the scope of the present invention, as long as they meet the purpose of the present invention. In addition, sizes and ratios of each member in drawings described hereinafter are for convenience, and they are different from real ones.

### First Exemplary Embodiment

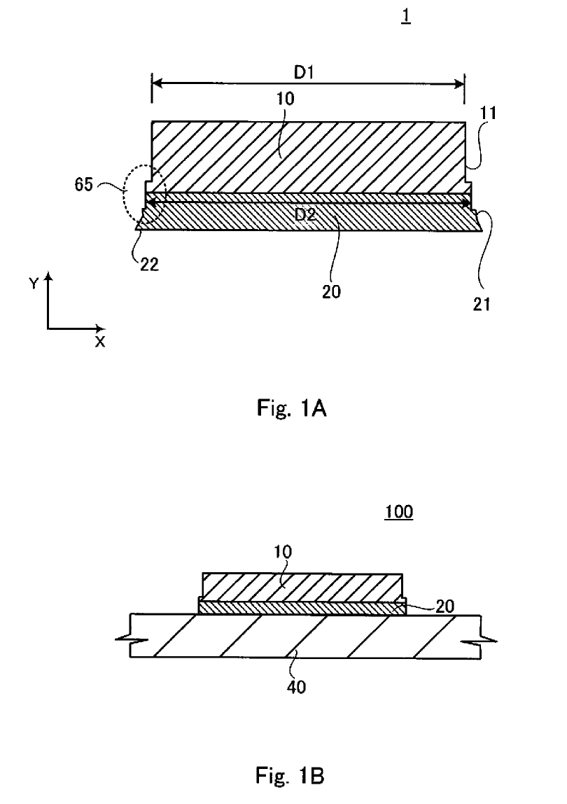

FIG. 1A is a schematic sectional view of a semiconductor chip 1 with a conductive adhesive layer according to a first exemplary embodiment of the invention. FIG. 1B is a schematic sectional view of a semiconductor device 100 which mounts the semiconductor chip 1 with the conductive adhesive layer on a substrate 40.

The semiconductor chip 1 with the conductive adhesive layer 1 includes a semiconductor chip 10 and a solder layer 20 as the conductive adhesive layer. The solder layer 20 is formed on the entire surface of the back side of the semiconductor chip 10. There are solder burrs 22, which are formed in the near field region of the backside that is opposite to the side where the semiconductor chip 10 is formed, at a sidewall 21 of the solder layer 20 and which is formed when the solder layer 20 is cut. A substantial formation direction of the solder burrs 22 are the major plane direction (X-direction in FIG. 1A) of the semiconductor chip 10 as shown in FIG. 1A.

Step structures 65 are formed from sidewall 11 of the semiconductor chip 10 to the sidewall 21 of the solder layer 20. The shape of the step structures 65 are as follows. That is, they are formed so that the outer size of the step structures at the solder layer 20 is greater than that at the front of the semiconductor chip 10. In the example shown in FIG. 1A, when outer size of the surface of the semiconductor chip 10 is assumed to be D1 and outer size of the solder layer 20 in the step structures 65 is assumed to be D2, D1<D2 is satisfied. In the first exemplary embodiment, the step portions of the step structures 65 are formed at the sidewall 11 of the semiconductor chip 10 and the sidewall of the solder layer 20 from the sidewall 11. However, the step structures may be formed only in the solder layer 20.

The semiconductor device 100 according to the first exemplary embodiment is configured such that the semiconductor chip 1 with the conductive adhesive layer is implemented on the substrate 40. The substrate 40 is not limited in particular in the range that does not deviate from a purpose of the present invention. For example, the substrate 40 is a printed circuit board or a lead frame. The semiconductor chip 1 with the conductive adhesive layer is put on the substrate 40 as shown in FIG. 1B, and is implemented on the substrate 40 by a reflow process.

In the semiconductor chip 1 with the conductive adhesive layer according to the first exemplary embodiment, because the solder layer 20 is formed on the back side of the semiconductor chip 10, it is not necessary to form a solder layer when it is implemented on the substrate 40. As a result, the simplification of the packaging process can be achieved.

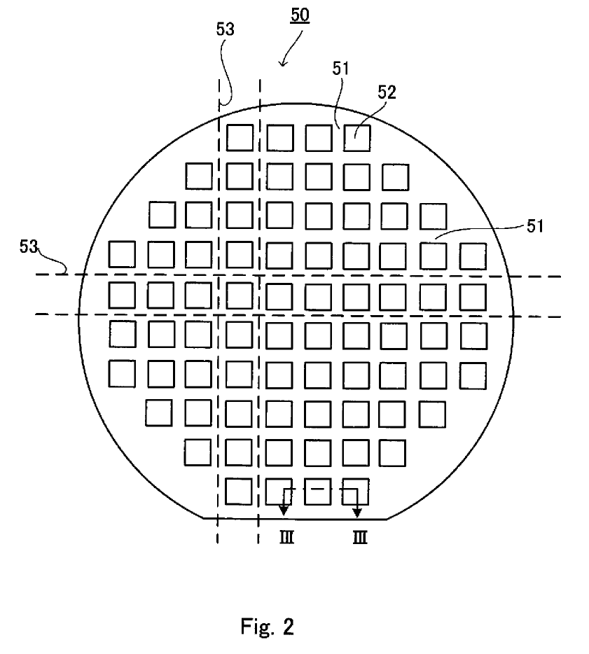

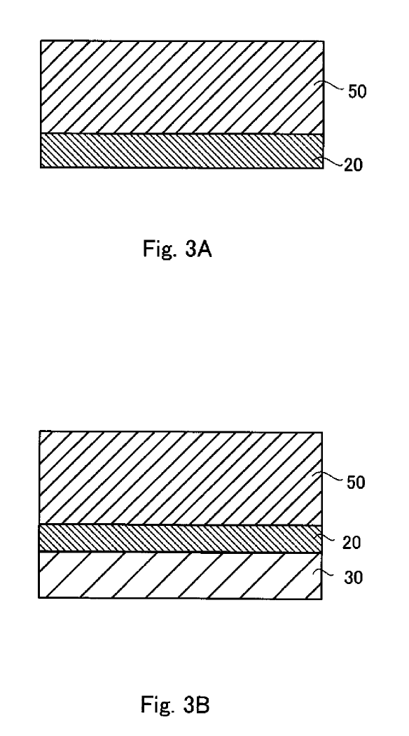

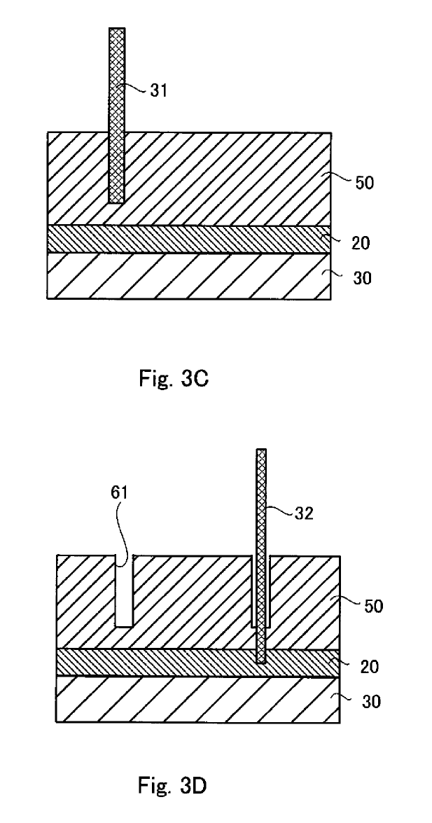

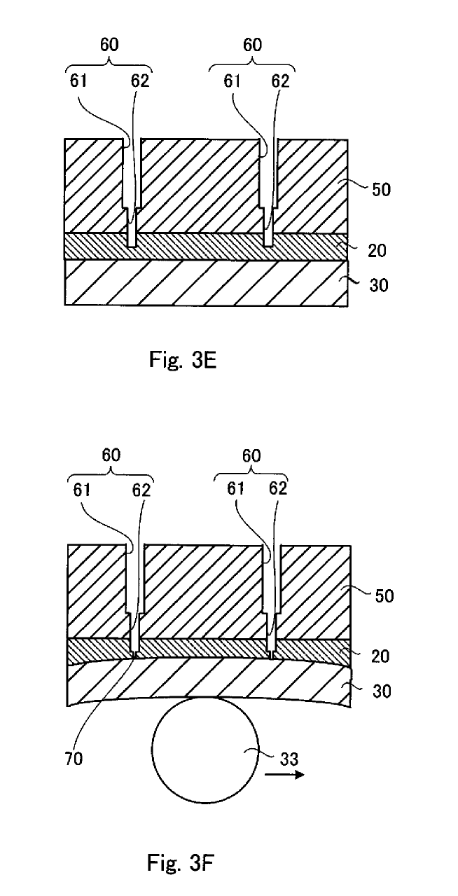

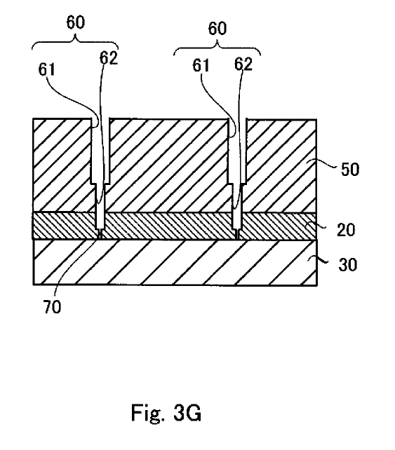

Then, about a method of manufacturing the semiconductor chip 1 with the conductive adhesive layer according to the first exemplary embodiment will be enplaned below with reference to FIG. 2 and FIGS. 3A to 3G. FIG. 2 is a schematic plane view of the wafer. FIGS. 3A to 3G are sectional views taken along the line III-III of FIG. 2.

At first, a wafer 50 on which a semiconductor element is formed is manufactured. The wafer 50 has scribe line areas 51 and a plurality of element formation areas 52 sectioned by the scribe line areas 51 as shown in FIG. 2. The element formation areas 52 are the areas where elements such as wirings, transistors, and resistances are formed. The element formation areas 52 are aligned to a longitudinal direction and a lateral direction. Meanwhile, the scribe line areas 51 are the areas where a dicing cut is performed along dicing lines 53 in a process to be described below.

Then, the solder layer 20 is formed on the back side of the wafer 50 (see FIG. 3A). The method of forming the solder layer 20 on the back side of the wafer 50 is not limited in particular, and well-known methods can be used without a limit. The thickness of the solder layer 20 is not limited in particular. However, 20 nm or more is preferable from a viewpoint of improving production yield. The upper limit of the thickness of the solder layer 20 is not limited in particular. However, it is usually 100 μm or less.

Continuously, a flexible substrate 30 is laminated on the back side of the solder layer 20 (see FIG. 3B). If the following conditions are satisfied, materials of the flexible substrate 30 are not limited in particular. The condition is as follows. That is, the solder layer 20 and the flexible substrate 30 can be fixedly laminated. Moreover, the solder layer 20 can be cut by a press means described below. Further still, the solder layer 20 and the flexible substrate 30 can be separated in a separation process described below. The material in which the adhesiveness and adhesive property is performed in a lamination process of the flexible substrate 30 and the solder layer 20 and the adhesiveness and the adhesive property disappear by ultraviolet irradiation or heat-treatment in the separation process thereof is preferred for the flexible substrate 30. The solder layer 20 and the flexible substrate 30 may be fixed with extra adhesive or tackiness agent. The thickness of the flexible substrate 30 is not limited in particular, too.

Subsequently, the dicing grooves 60 which reach from the front of the wafer 50 to the solder layer 20 and bottoms of which and bottoms of which are in the solder layer 20 are formed as follows (see FIGS. 3C to 3E). In other words, the dicing grooves 60 are formed so as not to reach to the flexible substrate 30.

The formation of the dicing grooves 60 can be performed by using a dicing blade. In the first exemplary embodiment, at first, first dicing grooves 61 opening to the halfway of the semiconductor chip 10 are formed so as not to penetrate the semiconductor chip 10 by using a first dicing blade 31. Subsequently, second dicing grooves 62 are formed as follows (see FIG. 3D). That is, the second dicing grooves 62 are formed so as to reach from the bottom of the first dicing grooves 61 to the solder layer 20, and bottoms thereof are in the solder layer 20. The second dicing grooves 62 are formed by using a second dicing blade 32 that has a smaller width in such a way that the width of the second dicing grooves 62 is smaller than that of the first dicing grooves 61 formed by the first dicing blade 31. As shown in FIG. 3E, the dicing grooves 60 are configured by the first dicing grooves 61 and the second dicing grooves 62.

Continuously, the flexible substrate 30 is rubs against from an underside of the flexible substrate 30 by using a braking roller 33 which is press means (see FIG. 3F). Thereby, braking lines 70 starting from the dicing grooves 60 are formed in the solder layer 20. Then, the solder layer 20 is cut (see FIG. 3G). At this time, the solder burrs 22 are formed.

Thereafter, the semiconductor chip 1 with the conductive adhesive layer as shown in FIG. 1A is obtained by separating the flexible substrate 30 from the solder layer 20. The processing to separate the flexible substrate 30 from the solder layer 20 can be used without a limit. From the viewpoint of ease of handling, the material in which the adhesion of the flexible substrate 30 and the solder layer 20 decreases by giving physical stimulation such as the ultraviolet rays, the heating, or the like is desirable.

In Japanese Unexamined Patent Application Publication No. 06-021109, as mentioned above, the solder burrs bite into the substrate 130 because the dicing grooves 160, which reach to the substrate 130 from the surface of the wafer 150 through the solder layer 120, are formed. Therefore, in the process of the die bonding, the semiconductor chip may not be picked up.

According to the first exemplary embodiment, because the dicing grooves 60 are formed from the surface of the wafer 50 to the halfway of the solder layer 20, the problem such as Japanese Unexamined Patent Application Publication No. 06-021109 does not occur.

In the method of Japanese Unexamined Patent Application Publication No. 08-236484, the adequacy of the braking power becomes important. Therefore, a complicated system that performs the load control of the braking roller is necessary. Thus, increase in cost was not avoided. Moreover, because the dicing grooves 260 disclosed in Japanese Unexamined Patent Application Publication No. 08-236484 are formed to reach to arrive at the inside of the wafer 250, a crack, a breaking and a chip are easy to occur in the side of the wafer when the braking lines 270 are formed in the wafer 250 by the braking roller 234. Thereby, products might become defective.

According to the first exemplary embodiment, because the cutting of the wafer 50 of the semiconductor chip is completed in the dicing process, it is possible to prevent the crack and the breaking off such as in Japanese Unexamined Patent Application Publication No. 08-236484 from being formed at the side of the semiconductor chip. Moreover, according to the first exemplary embodiment, the braking roller 33 touches to the wafer 50 from the bottom thereof and rubs thereon without reversing a major plane of the wafer 50. Therefore, it is possible to simplify the manufacturing process. Note that, it is not excluded to reverse the major plane of the wafer 50 when press means such as the braking roller 33 is performed. The major plane of the wafer 50 may be reversed as needed.

According to the first exemplary embodiment, because it is only the pressuring force from the underside of the flexible substrate 30 and a delicate load control such as in Japanese Unexamined Patent Application Publication No. 08-236484 is unnecessary, it is possible to simplify the mechanism of the device. Further, because only power for extending the solder layer 20 should be added when the press means is performed, it is not necessary to set up such as the resilient base 233 at the opposite side of the wafer sheet 230 such as Japanese Unexamined Patent Application Publication No. 08-236484.

Note that, in the first exemplary embodiment, the example in which formed the first dicing grooves 61 and the second dicing grooves 62 are formed by using two dicing blades is described. However, the dicing grooves 60 may be formed by using one dicing blade having two kinds of width.

### Second Exemplary Embodiment

Next, another exemplary embodiment will be described in which a semiconductor chip with a conductive adhesive layer different from the above-described first exemplary embodiment. In the drawings described below, the same component members as in the above-described first embodiment have the same reference numerals, and explanations thereof are arbitrarily omitted.

As for the semiconductor chip with the conductive adhesive layer according to the second exemplary embodiment, the basic configuration except for the following points is similar to that of the first exemplary embodiment. That is, in the first exemplary embodiment, the step structures 65 are formed in sidewall of the semiconductor chip 10 and the solder layer 20. Meanwhile, in the second exemplary embodiment, taper is formed in the sidewall.

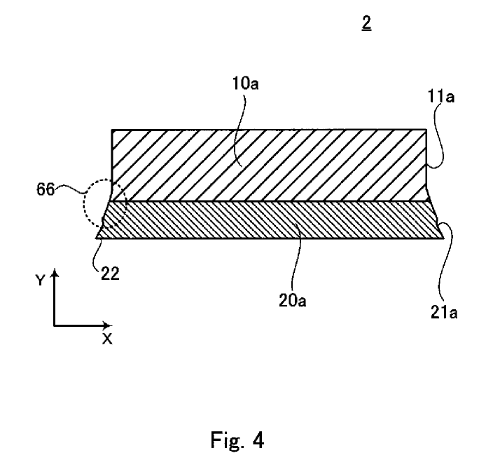

FIG. 4 is a schematic cross-sectional view of the semiconductor chip 2 with the conductive adhesive layer according to the second exemplary embodiment. The semiconductor chip 2 with the conductive adhesive layer includes a semiconductor chip 10a and a solder layer 20a as the conductive adhesive layer. The solder layer 20a is formed on the entire surface of the back side of the semiconductor chip 10a. At sidewall 21a of the solder layer 20a, in the near field region of the back side that is opposite to a side where the front of the semiconductor chip 10a is formed there are solder burrs 22 which are formed when the solder layer 20a is cut. A substantial formation direction of the solder burrs 22 is the major plane direction (X-direction in FIG. 4) of the semiconductor chip 10a as shown in FIG. 4.

The taper 66, outer size of which gradually increases with distance from the semiconductor chip, is formed from the sidewall 11a of the semiconductor chip 10a to sidewall 21a of the solder layer 20a. The taper 66 may be formed only in the solder layer 20a.

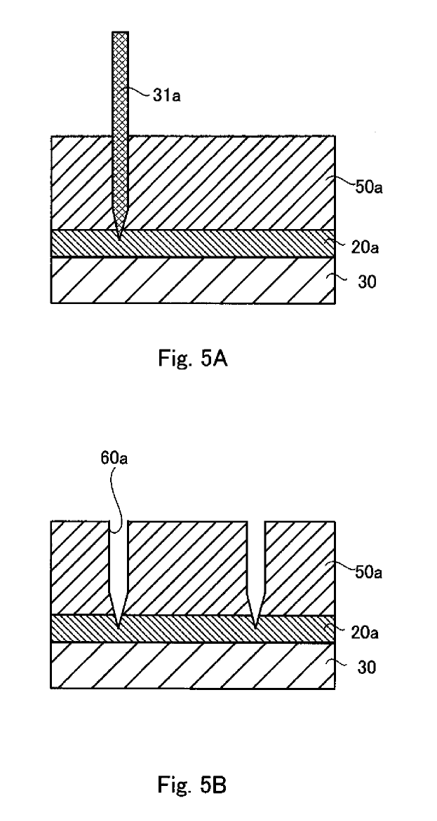

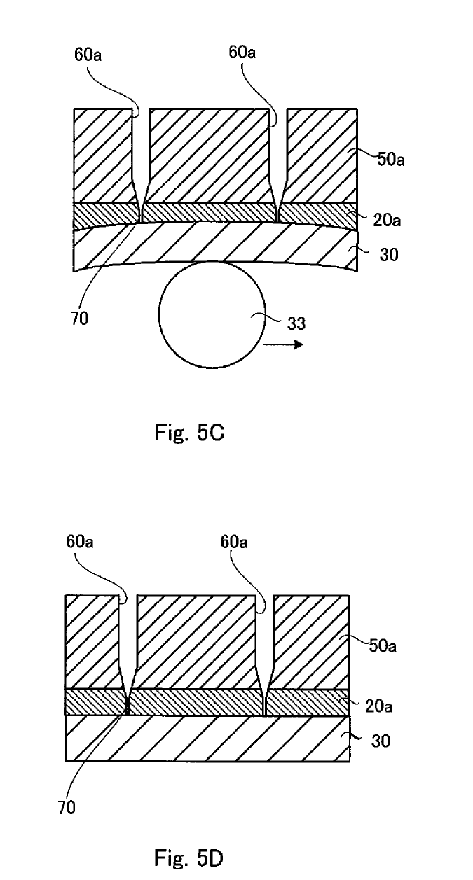

Then, a method of manufacturing the semiconductor chip 2 with the conductive adhesive layer according to the second exemplary embodiment will be explained below with reference to FIGS. 5A to 5D.

The solder layer 20a is formed on the back side of the wafer 50a (see FIG. 2), and the flexible substrate 30 is laminated on the back side of the solder layer 20a. It is similar to the first exemplary embodiment thus far. Subsequently, the dicing grooves 60a which reach from the front of the wafer 50a to the solder layer 20a and bottoms of which are in the solder layer 20a are formed (see FIG. 5A). In other words, the dicing grooves 60a are formed so as not to reach to the flexible substrate 30.

The formation of the dicing grooves 60a can be performed by using a dicing blade 31a. In the second exemplary embodiment, the dicing grooves 60a are formed by using the dicing blade 31a the tip of which has a V-shaped (see FIGS. 5A and 5B).

Continuously, the flexible substrate 30 is rubbed against from an underside of the flexible substrate 30 by using a braking roller 33 which is press means (see FIG. 5C). Thereby, braking lines 70 starting from the dicing grooves 60a are formed in the solder layer 20a. The solder layer 20a is cut in the depth direction of the dicing grooves 60a (see FIG. 3D).

Thereafter, the semiconductor chip 2 with the conductive adhesive layer as shown in FIG. 4 is obtained by separating the flexible substrate 30 from the solder layer 20a.

According to the second exemplary embodiment, the same effect same as the first exemplary embodiment can be obtained. Moreover, according to the second exemplary embodiment, because the tip of the dicing blade has the angle rather than the flat, it is possible to suppress the formation of a crack more effectively when it is rubbed with the braking roller. Moreover, because the tip of the cut surface of the dicing grooves 60a has the V-shape, stress that works on the tip of the cut surface of the dicing grooves 60a can be raised when it is rubbed by using the braking roller 33. As a result, a superior effect that separation of the solder layer 20a becomes easier is provided.

### Third Exemplary Embodiment

Next, an example of a semiconductor chip with a conductive adhesive layer different from the above-described first and second exemplary embodiments. As for the semiconductor chip with the conductive adhesive layer according to the third exemplary embodiment, the basic configuration except for the following points is similar to that of the first exemplary embodiment. That is, in the first exemplary embodiment, the dicing grooves 60 having two kinds of width are formed. Meanwhile, in the third exemplary embodiment, dicing grooves having the same width are formed.

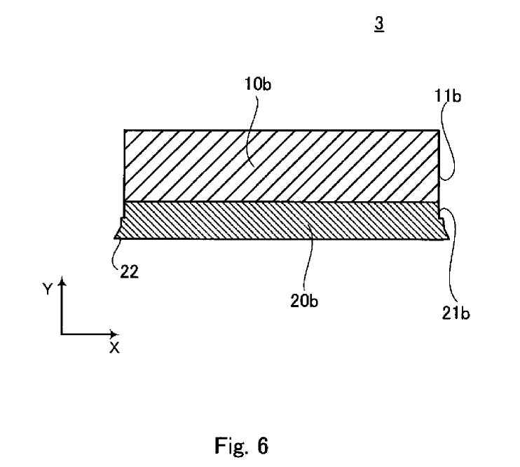

FIG. 6 is a schematic cross-sectional view of the semiconductor chip 3 with the conductive adhesive layer according to the third exemplary embodiment. The semiconductor chip 3 with the conductive adhesive layer includes a semiconductor chip 10b and a solder layer 20b as the conductive adhesive layer. The solder layer 20b is formed on the entire surface of the back side of the semiconductor chip 10b. At sidewall 21b of the solder layer 20b, in the near field region of the back side that is opposite to a side where the front of the semiconductor chip 10b is formed, there are solder burrs 22 which are formed when the solder layer 20b is cut. A substantial formation direction of the solder burrs 22 is the major plane direction (X-direction in FIG. 6) of the semiconductor chip 10b as shown in FIG. 6.

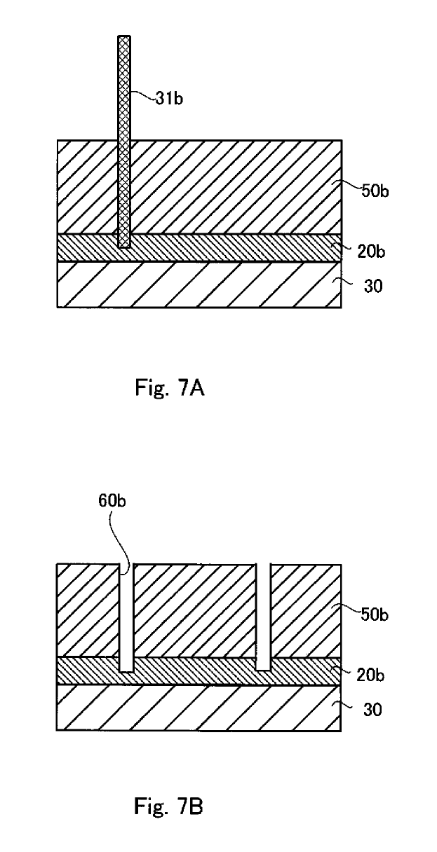

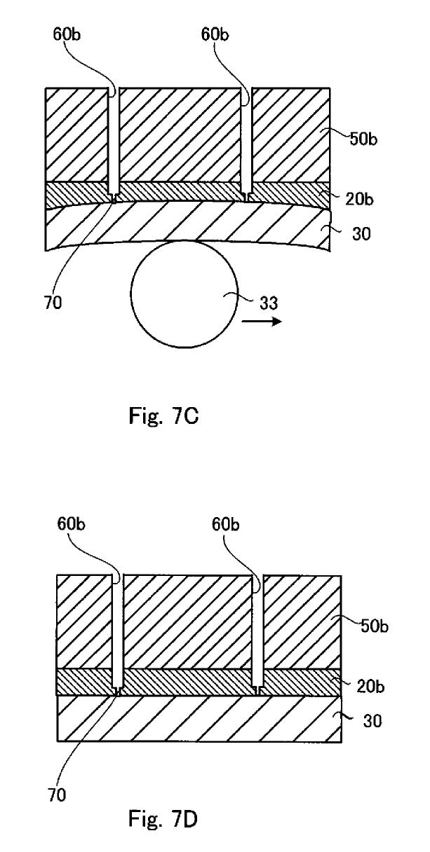

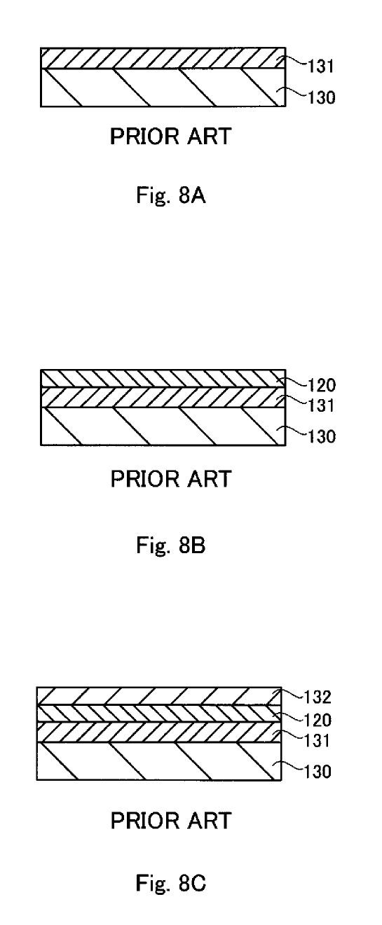

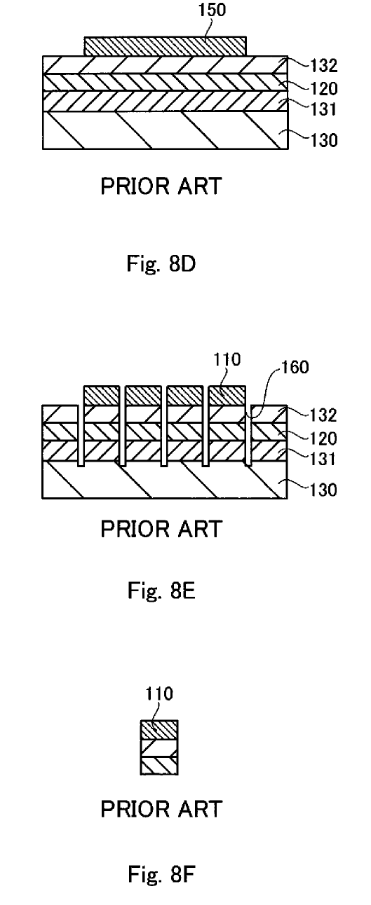

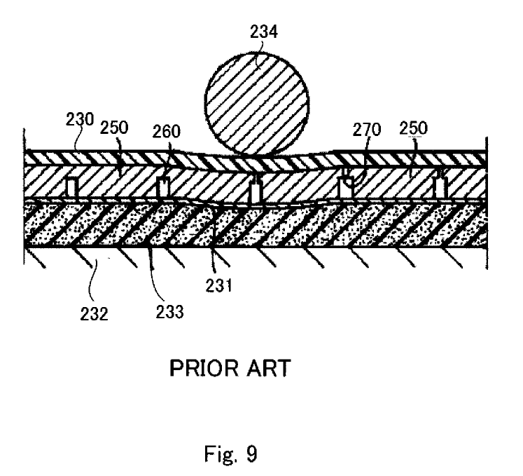

Then, about a method of manufacturing the semiconductor chip 3 with the conductive adhesive layer according to the third exemplary embodiment will be explained below with reference to FIGS. 7A to 7D.

The solder layer 20b is formed on the back side of the wafer 50b, and the flexible substrate 30 is laminated on the back side of the solder layer 20b. It is similar to the first exemplary embodiment thus far. Subsequently, the dicing grooves 60b which reach from the front of the wafer 50b to the solder layer 20b and bottoms of which are in the solder layer 20b are formed (see FIG. 7A).

The formation of the dicing grooves 60b can be performed by using a dicing blade 31b. In the third exemplary embodiment, the dicing grooves 60b are formed by using the dicing blade 31b that the tip of which has a flat-shaped (see FIG. 7A).

Continuously, the flexible substrate 30 is rubbed against from an underside of the flexible substrate 30 by using a braking roller 33 which is press means (see FIG. 7C). Thereby, braking lines 70 starting from the dicing grooves 60b are formed in the solder layer 20b (see FIG. 7B).

Thereafter, the semiconductor chip 3 with the conductive adhesive layer as shown in FIG. 6 is obtained by separating the flexible substrate 30 from the solder layer 20b.

Note that, in the first to third exemplary embodiments, the examples in which the solder layer is used as the conductive adhesive layer was described. However, the conductive adhesive layer is not limited to the solder layer, and a conductive adhesive layer according to the present invention can be applied without a limit to materials having a similar function. Moreover, the example in which the braking roller is used as the press means when the solder layer is cut is described. However, the pressure means should not be limited, on the condition that they may form the braking line in the solder layer by pressing from the back side of the flexible substrate 30 and separate the solder layer. For example, other examples of the press means can include an air or a blade. Moreover, the shape of the sidewall of the semiconductor chip with the conductive adhesive layer is not limited to an example nominated for the first to third exemplary embodiments, and various kinds of transformation is possible in the range that does not deviate from a purpose of the present invention.

Each of the above-described embodiments can be combined as desirable by one of ordinary skill in the art.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A method of manufacturing a semiconductor chip with a conductive adhesive layer comprising steps of:
forming a conductive adhesive layer on back side of a wafer on which a semiconductor element is formed;
laminating a flexible substrate on back side of the conductive adhesive layer;
forming a dicing groove which reaches from a front of the wafer to the conductive adhesive layer and a bottom of which is in the conductive adhesive layer;
pressing from back side of the flexible substrate in such a way that the conductive adhesive layer is cut with the dicing groove as an origin point; and
separating the flexible substrate from the conductive adhesive layer.

2. The method of manufacturing the semiconductor chip with the conductive adhesive layer according to claim 1, wherein
the conductive adhesive layer is a solder layer.

3. The method of manufacturing the semiconductor chip with the conductive adhesive layer according to claim 1, wherein
the dicing groove is formed so that the width of an opening at a front of the conductive adhesive layer is narrower than that at a front of the semiconductor chip.

4. The method of manufacturing the semiconductor chip with the conductive adhesive layer according to claim 1, wherein
in the step of forming the dicing groove, the dicing groove is formed so that a shape of the dicing groove that is formed at the conductive adhesive layer is at least V-shaped.

5. The method of manufacturing the semiconductor chip with the conductive adhesive layer according to claim 1, wherein
the step of forming the dicing groove includes steps of;
forming a first dicing groove until the halfway of the wafer,
subsequently, forming a second dicing groove from the bottom of the first dicing groove to the halfway of the conductive adhesive layer, the width of the second dicing groove is narrower than that of the first dicing groove.

6. A method of manufacturing a semiconductor device that implements a semiconductor chip with a conductive adhesive layer comprising steps of:
manufacturing a semiconductor chip;
mounting the semiconductor chip so that the conductive adhesive layer, which is formed on back side of the semiconductor chip, is attached on a substrate; and
implementing the semiconductor chip with conductive adhesive layer on the substrate by a reflow process; wherein
the method of manufacturing the semiconductor chip with conductive adhesive layer comprising steps of:
forming the conductive adhesive layer in the back side of a wafer which a semiconductor element is formed;
laminating a flexible substrate in the back side of the conductive adhesive layer;
forming a conductive adhesive layer on back side of a wafer on which a semiconductor element is formed;
laminating a flexible substrate on back side of the conductive adhesive layer;
forming a dicing groove which reaches from a front of the wafer to the conductive adhesive layer and a bottom of which is in the conductive adhesive layer;
pressing from back side of the flexible substrate in such a way that the conductive adhesive layer is cut with the dicing groove as an origin point; and
separating the flexible substrate from the conductive adhesive layer.

7. The method of manufacturing the semiconductor device according to claim 6, wherein
the conductive adhesive layer is a solder layer.

8. The method of manufacturing the semiconductor chip with conductive adhesive layer according to claim 6, wherein
the dicing groove is formed so that the width of an opening at a front of the conductive adhesive layer is narrower than that at a front of the semiconductor chip.

9. The method of manufacturing the semiconductor chip with conductive adhesive layer according to claim 6, wherein
in the step of forming the dicing groove, the dicing groove is formed so that a shape of the dicing groove that is formed at the conductive adhesive layer is at least V-shaped.

10. The method of manufacturing the semiconductor chip with a conductive adhesive layer according to claim 6, wherein
the step of forming the dicing groove includes steps of;
forming a first dicing groove until the halfway of the wafer,
subsequently, forming a second dicing groove from the bottom of the first dicing grooves to the halfway of the conductive adhesive layer, the width of the second dicing groove is narrower than the width of the first dicing groove.

11. A semiconductor chip with a conductive adhesive layer comprising:
a semiconductor chip; and
a conductive adhesive layer formed on back side of the semiconductor chip; wherein
solder burr which is substantively extended in the major plane direction of the semiconductor chip is formed in a near field region of the back side that is opposite to a side where the semiconductor chip is formed, at a sidewall of the conductive adhesive layer, when the conductive adhesive layer is cut.

12. The semiconductor chip with the conductive adhesive layer according to claim 11, wherein
the conductive adhesive layer is a solder layer.

13. The semiconductor chip with the conductive adhesive layer according to claim 11, wherein
wherein a taper, outer size of which gradually increases with distance from the semiconductor chip, is formed at least in the near field region on the semiconductor chip side of the conductive adhesive layer at sidewall of the semiconductor chip and the conductive adhesive layer.

14. The semiconductor chip with the conductive adhesive layer according to claim 11, wherein
step structure, outer size of which near the back side of the conductive adhesive layer is greater than that at the front of the semiconductor chip, is formed at least in the near field region on the semiconductor chip side of the conductive adhesive layer at sidewall of the semiconductor chip and the conductive adhesive layer.
